(19) United States
(12) Patent Application Publication
(10) Pub. No.: US 2018/0109145 A1
(43) Pub. Date: Apr. 19, 2018

(54) POWER DISSIPATION CONTROL FOR A WIRELESS POWER RECEIVER

(71) Applicant: QUALCOMM Incorporated, San Diego, CA (US)

(72) Inventors: William Henry VON NOVAK, III, San Diego, CA (US); Mark WHITE, II, San Diego, CA (US); Eric MATTIS, San Diego, CA (US)

(21) Appl. No.: 15/676,275

(22) Filed: Aug. 14, 2017

Related U.S. Application Data
(60) Provisional application No. 62/408,934, filed on Oct. 17, 2016.

(51) Int. Cl. H02J 50/12; H03H 7/40

(52) U.S. Cl. CPC H02J 50/12; H02J 7/025; H03H 7/40

(57) ABSTRACT

Certain aspects of the present disclosure relate to methods and apparatus for power dissipation control for a wireless power receiver. Certain aspects of the present disclosure provide a wireless power receiver. The wireless power receiver includes a resonator including an inductor and a capacitor. The resonator is configured to couple to a wireless field. The wireless field induces a voltage in the resonator. The capacitor is coupled to the inductor. The capacitor is configured to at least one of shunt tune or series tune the resonator. The wireless power receiver further includes a control circuit configured to at least one of selectively couple the capacitor to the inductor or adjust a capacitance of the capacitor based on at least one of a temperature near the wireless power receiver or an electrical characteristic of a thermally conductive path between the wireless power receiver and a surrounding thermal environment.

### CROSS-REFERENCE TO RELATED APPLICATIONS

This application claims the benefit of U.S. Provisional Patent No. 62/408,934, filed Oct. 17, 2016. The content of the provisional application is hereby incorporated by reference in its entirety.

### TECHNICAL FIELD

The present disclosure relates generally to wireless power transfer, and in particular to power dissipation control for a wireless power receiver.

BACKGROUND

Wireless power transfer systems can be used to charge and/or power electronic devices without physical, electrical connections. Such wireless power transfer systems can reduce the number of components required for operation of the electronic devices and simplify the use of the electronic device. Further, such wireless power transfer systems can be used to power electronic devices in areas that are not necessarily accessible to provide wired power transfer.

For example, some electronic devices, such as medical implants (e.g., pacemakers, neuromodulation devices, insulin pumps, brain implants, etc.) may be located/positioned in areas where replacing the battery in the device, or even including a battery in the device is not always feasible (e.g., in a body, such as, a human body), and providing wired access to the device is also not desirable or feasible. For example, to change a battery for a medical implant, surgery may need to be performed, which is risky. Further, implants may be in highly sensitive areas (e.g., the brain) where inclusion of a battery is risky (e.g., due to potential faulty operation of the battery). Accordingly, it may be safer to power/charge such devices wirelessly.

Further, the use of wireless power may eliminate the need for cords/cables to be attached to the electronic devices, which may be inconvenient and aesthetically displeasing.

Different electronic devices may have different shapes, sizes, and power requirements. There is flexibility in having different sizes and shapes in the components (e.g., magnetic coil, charging plate, etc.) that make up a wireless power transmitter and/or a wireless power receiver in terms of industrial design and support for a wide range of devices

### SUMMARY

Certain aspects of the present disclosure provide a wireless power receiver. The wireless power receiver includes a resonator including an inductor and a capacitor. The resonator is configured to couple to a wireless field. The wireless field induces a voltage in the resonator. The capacitor is coupled to the inductor. The capacitor is configured to at least one of shunt tune or series tune the resonator. The wireless power receiver further includes a control circuit configured to at least one of selectively couple the capacitor to the inductor or adjust a capacitance of the capacitor based on at least one of a temperature near the wireless power receiver or an electrical characteristic of a thermally conductive path between the wireless power receiver and a surrounding thermal environment, wherein the control circuit is configured to at least one of selectively couple the capacitor to the inductor or adjust the capacitance of the capacitor to change an efficiency of the wireless power receiver to adjust the temperature near the wireless power receiver.

Certain aspects of the present disclosure provide a method for controlling power dissipation in a wireless power receiver. The method includes coupling a resonator to a wireless field to induce a voltage in the resonator. The method further includes measuring at least one of a temperature near the wireless power receiver or an electrical characteristic of a thermally conductive path between the wireless power receiver and a surrounding thermal environment. The method further includes adjusting a series tuning or shunt tuning of the resonator based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

Certain aspects of the present disclosure provide a wireless power receiver. The wireless power receiver includes means for measuring at least one of a temperature near the wireless power receiver or an electrical characteristic of a thermally conductive path between the wireless power receiver and a surrounding thermal environment. The wireless power receiver further includes means for adjusting a series tuning or shunt tuning of a resonator of the wireless power receiver based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

Certain aspects of the present disclosure provide a computer-readable storage medium having instructions stored thereon for performing a method for controlling power dissipation in a wireless power receiver. The method includes measuring at least one of a temperature near the wireless power receiver or an electrical characteristic of a thermally conductive path between the wireless power receiver and a surrounding thermal environment. The method further includes adjusting a series tuning or shunt tuning of a resonator of the wireless power receiver based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

The following detailed description and accompanying drawings provide a better understanding of the nature and advantages of the present disclosure.

### BRIEF DESCRIPTION OF THE DRAWINGS

With respect to the discussion to follow and in particular to the drawings, it is stressed that the particulars shown represent examples for purposes of illustrative discussion, and are presented in the cause of providing a description of principles and conceptual aspects of the present disclosure. In this regard, no attempt is made to show implementation details beyond what is needed for a fundamental understanding of the present disclosure. The discussion to follow, in conjunction with the drawings, makes apparent to those of skill in the art how embodiments in accordance with the present disclosure may be practiced. In the accompanying drawings:

FIG. 1 is a functional block diagram of a wireless power transfer system in accordance with an illustrative aspect.

FIG. 2 is a functional block diagram of a wireless power transfer system in accordance with an illustrative aspect.

FIG. 3 is a schematic diagram of a portion of transmit circuitry or receive circuitry of FIG. 2 including a power transmitting or receiving element in accordance with an illustrative aspect.

FIG. 4 is a circuit diagram of an example of a wireless power receiver, in accordance with certain aspects of the present disclosure.

FIG. 4A is a circuit diagram of an example of a wireless power receiver, in accordance with certain aspects of the present disclosure.

FIG. 5 is a graph that illustrates an example power output of a wireless power receiver versus a power dissipated by the wireless power receiver, in accordance with certain aspects of the present disclosure.

FIG. 6 is a flowchart of example operations for adjusting capacitance in a resonator of a wireless power receiver, in accordance with certain aspects of the present disclosure.

### DETAILED DESCRIPTION

Drawing elements that are common among the following figures may be identified using the same reference numerals.

Wireless power transfer may refer to transferring any form of energy associated with electric fields, magnetic fields, electromagnetic fields, or otherwise from a transmitter to a receiver without the use of physical electrical conductors (e.g., power may be transferred through free space). The power output into a wireless field (e.g., a magnetic field or an electromagnetic field) may be received, captured by, or coupled by a “power receiving element” to achieve power transfer.

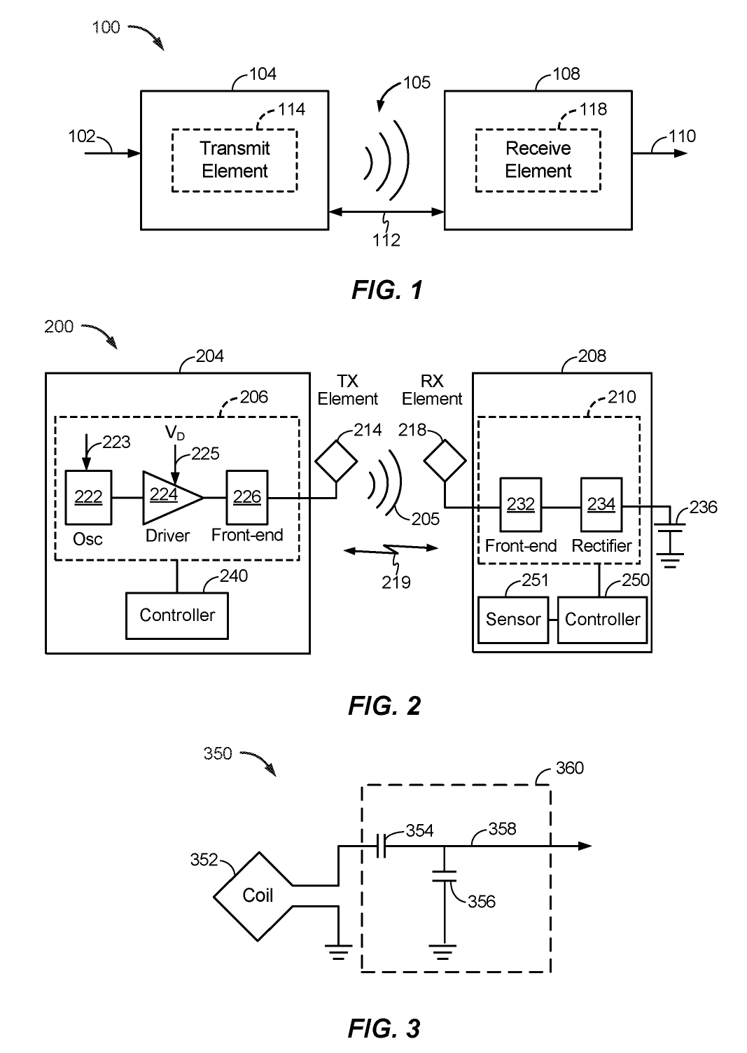

FIG. 1 is a functional block diagram of a wireless power transfer system 100, in accordance with an illustrative aspect. Input power 102 may be provided to a transmitter 104 from a power source (not shown in this figure) to generate a wireless (e.g., magnetic or electromagnetic) field 105 for performing energy transfer. A receiver 108 may couple to the wireless field 105 and generate output power 110 for storing or consumption by a device (not shown in this figure) coupled to the output power 110. The transmitter 104 and the receiver 108 may be separated by a distance 112. The transmitter 104 may include a power transmitting element 114 for transmitting/coupling energy to the receiver 108. The receiver 108 may include a power receiving element 118 for receiving or capturing/coupling energy transmitted from the transmitter 104.

In one illustrative aspect, the transmitter 104 and the receiver 108 may be configured according to a mutual resonant relationship. When the resonant frequency of the receiver 108 and the resonant frequency of the transmitter 104 are substantially the same or very close, transmission losses between the transmitter 104 and the receiver 108 are reduced. As such, wireless power transfer may be provided over larger distances. Resonant inductive coupling techniques may thus allow for improved efficiency and power transfer over various distances and with a variety of inductive power transmitting and receiving element configurations.

In certain aspects, the wireless field 105 may correspond to the “near field” of the transmitter 104. The near-field may correspond to a region in which there are strong reactive fields resulting from the currents and charges in the power transmitting element 114 that minimally radiate power away from the power transmitting element 114. The near-field may correspond to a region that is within about one wavelength (or a fraction thereof) of the power transmitting element 114. Conversely, the far field may correspond to a region that is greater than about one wavelength of the power transmitting element 114.

In certain aspects, efficient energy transfer may occur by coupling a large portion of the energy in the wireless field 105 to the power receiving element 118 rather than propagating most of the energy in an electromagnetic wave to the far field.

In certain implementations, the transmitter 104 may output a time varying magnetic (or electromagnetic) field with a frequency corresponding to the resonant frequency of the power transmitting element 114. When the receiver 108 is within the wireless field 105, the time varying magnetic (or electromagnetic) field may induce a current in the power receiving element 118. As described above, if the power receiving element 118 is configured as a resonant circuit to resonate at the frequency of the power transmitting element 114, energy may be efficiently transferred. An alternating current (AC) signal induced in the power receiving element 118 may be rectified to produce a direct current (DC) signal that may be provided to charge or to power a load.

FIG. 2 is a functional block diagram of a wireless power transfer system 200, in accordance with another illustrative aspect. The system 200 may include a transmitter 204 and a receiver 208. The transmitter 204 (also referred to herein as power transfer unit, PTU) may include transmit circuitry 206 that may include an oscillator 222, a driver circuit 224, and a front-end circuit 226. The oscillator 222 may be configured to generate an oscillator signal (e.g., an oscillating signal) at a desired frequency (e.g., fundamental frequency) that may adjust in response to a frequency control signal 223. The oscillator 222 may provide the oscillator signal to the driver circuit 224. The driver circuit 224 may be configured to drive the power transmitting element 214 at, for example, a resonant frequency of the power transmitting element 214 based on an input voltage signal (VD) 225. The driver circuit 224 may be a switching amplifier configured to receive a square wave from the oscillator 222 and output as a driving signal output a sine wave.

The front-end circuit 226 may include a filter circuit configured to filter out harmonics or other unwanted frequencies. The front-end circuit 226 may include a matching circuit configured to match the impedance of the transmitter 204 to the impedance of the power transmitting element 214. As will be explained in more detail below, the front-end circuit 226 may include a tuning circuit to create a resonant circuit with the power transmitting element 214. As a result of driving the power transmitting element 214, the power transmitting element 214 may generate a wireless field 205 to wirelessly output power at a level sufficient for charging a battery 236, or otherwise powering a load (e.g., an implant without a battery 236).

The transmitter 204 may further include a controller 240 operably coupled to the transmit circuitry 206 and configured to control one or more aspects of the transmit circuitry 206, or accomplish other operations relevant to managing the transfer of power. The controller 240 may be a micro-controller or a processor. The controller 240 may be implemented as an application-specific integrated circuit (ASIC). The controller 240 may be operably connected, directly or indirectly, to each component of the transmit circuitry 206. The controller 240 may be further configured to receive information from each of the components of the transmit circuitry 206 and perform calculations based on the received information. The controller 240 may be configured to generate control signals (e.g., signal 223) for each of the components that may adjust the operation of that component. As such, the controller 240 may be configured to adjust or manage the power transfer based on a result of the operations performed by it. The transmitter 204 may further include a memory (not shown) configured to store data, for example, such as instructions for causing the controller 240 to perform particular functions, such as those related to management of wireless power transfer.

The receiver 208 (also referred to herein as power receiving unit, PRU) may include receive circuitry 210 that may include a front-end circuit 232 and a rectifier circuit 234. The front-end circuit 232 may include matching circuitry configured to match the impedance of the receive circuitry 210 to the impedance of the power receiving element 218. As will be explained below, the front-end circuit 232 may further include a tuning circuit to create a resonant circuit with the power receiving element 218. The rectifier circuit 234 may generate a DC power output from an AC power input to charge the battery 236 or power a load, as shown in FIG. 2. The receiver 208 and the transmitter 204 may additionally communicate on a separate communication channel 219 (e.g., Bluetooth, Zigbee, cellular, etc.). The receiver 208 and the transmitter 204 may alternatively communicate via in-band signaling using characteristics of the wireless field 205.

The receiver 208 may be configured to determine whether an amount of power transmitted by the transmitter 204 and received by the receiver 208 is appropriate for charging the battery 236 or powering a load. In certain aspects, the transmitter 204 may be configured to generate a predominantly non-radiative field with a direct field coupling coefficient (k) for providing energy transfer. Receiver 208 may directly couple to the wireless field 205 and may generate an output power for storing or consumption by a battery (or load) 236 coupled to the output or receive circuitry 210.

The receiver 208 may further include a controller 250 configured similarly to the transmit controller 240 as described above for managing one or more aspects of the wireless power receiver 208. In some aspects, the controller 250 is configured to control one or more switches (e.g., transistors) of the receiver 208, such as, for selectively coupling and decoupling capacitors of the receiver 208 to change at least one of a series or shunt tuning of the receiver 208 or selectively coupling or decoupling the power receiving element 218 from the rectifier 234. For example, the controller 250 may be configured to selectively apply a voltage (e.g., from a voltage supply, such as the rectifier 234) to a gate terminal of the switches to selectively open and close the switches. In some aspects, the controller 250 is configured to control the capacitance of variable capacitors of the receiver 208 to change at least one of a series or shunt tuning of the receiver 208. In some aspects, the controller 250 is configured to control the switches and/or capacitance of variable capacitors based on a temperature near the receiver 208 (e.g., a temperature of a load coupled to the receiver 208, of a case or housing of the receiver 208, etc.) and/or based on electrical characteristic (e.g., impedance or capacitance) of a thermally conductive path between the wireless power receiver and a surround thermal environment of the load (e.g., when the load is a brain implant comprising nanotubes coupled to neurons). For example, the controller 250, in some aspects, is coupled to a sensor 251 and/or additional sensors. The sensor 251 may be a temperature sensor, impedance measuring circuit, capacitance measuring circuit, etc., configured to indicate temperature or an electrical property to the controller 250. For example, in some aspects the sensor 251 measures electrical properties (e.g., impedance, capacitance, etc.) of nanotubes of a brain implant or nanotubes of the sensor 251 to determine temperature in a local region of the brain. In some aspects, the sensor 251 measures temperature directly. In some aspects, the controller 250 may comprise an integrated circuit, power management integrated circuit (PMIC), processor, etc.

The receiver 208 may further include a memory (not shown) configured to store data, for example, such as instructions for causing the controller 250 to perform particular functions, such as those related to management of wireless power transfer.

As discussed above, transmitter 204 and receiver 208 may be separated by a distance and may be configured according to a mutual resonant relationship to minimize transmission losses between the transmitter 204 and the receiver 208.

FIG. 3 is a schematic diagram of a portion of the transmit circuitry 206 or the receive circuitry 210 of FIG. 2, in accordance with illustrative aspects. As illustrated in FIG. 3, transmit or receive circuitry 350 may include a power transmitting or receiving element 352 and a tuning circuit 360. The power transmitting or receiving element 352 may also be referred to or be configured as an antenna or a “loop” antenna. The term “antenna” generally refers to a component that may wirelessly output or receive energy for coupling to another antenna. The power transmitting or receiving element 352 may also be referred to herein or be configured as a “magnetic” antenna, or an induction coil, a resonator, or a portion of a resonator. The power transmitting or receiving element 352 may also be referred to as a coil or resonator of a type that is configured to wirelessly output or receive power. As used herein, the power transmitting or receiving element 352 is an example of a “power transfer component” of a type that is configured to wirelessly output and/or receive power. The power transmitting or receiving element 352 may include an air core or a physical core such as a ferrite core (not shown in this figure). In some aspects, the term resonator, as used herein may refer to the entire resonant circuit including an inductor in combination with the capacitance of one or more capacitors of the resonant circuit.

When the power transmitting or receiving element 352 is configured as a resonant circuit or resonator with tuning circuit 360, the resonant frequency of the power transmitting or receiving element 352 may be based on the inductance and capacitance. Inductance may be simply the inductance created by a coil and/or other inductor forming the power transmitting or receiving element 352. Capacitance (e.g., a capacitor) may be provided by the tuning circuit 360 to create a resonant structure at a desired resonant frequency. As a non limiting example, the tuning circuit 360 may comprise a capacitor 354 and a capacitor 356, which may be added to the transmit and/or receive circuitry 350 to create a resonant circuit.

The tuning circuit 360 may include other components to form a resonant circuit with the power transmitting or receiving element 352. As another non limiting example, the tuning circuit 360 may include a capacitor (not shown) placed in parallel between the two terminals of the circuitry 350. Still other designs are possible. In some aspects, the tuning circuit in the front-end circuit 226 may have the same design (e.g., 360) as the tuning circuit in front-end circuit 232. In other aspects, the front-end circuit 226 may use a tuning circuit design different than in the front-end circuit 232.

For power transmitting elements, the signal 358, with a frequency that substantially corresponds to the resonant frequency of the power transmitting or receiving element 352, may be an input to the power transmitting or receiving element 352. For power receiving elements, the signal 358, with a frequency that substantially corresponds to the resonant frequency of the power transmitting or receiving element 352, may be an output from the power transmitting or receiving element 352. Although aspects disclosed herein may be generally directed to resonant wireless power transfer, persons of ordinary skill will appreciate that aspects disclosed herein may be used in non-resonant implementations for wireless power transfer.

In certain aspects, a portion of the power received at a wireless power receiver (e.g., receiver 208) may be dissipated by the wireless power receiver. For example, a portion of the power received by receiver 208 (e.g., corresponding to the receive circuitry 350) may be dissipated. In some aspects, such power dissipation by the receiver 208 may take the form of heat dissipated in areas near the receiver 208. The dissipated heat may therefore affect the temperature of areas near the receiver 208.

In some aspects, the areas near the receiver 208 may need to be temperature controlled. For example, the receiver 208 may be part of a medical implant, such as a brain implant (e.g., used for deep brain stimulation). For example, the brain implant may include circuitry that implements the functionality of the implant that acts as a load powered by the receiver 208. The brain implant may pose a significant thermal risk to the brain. Accordingly, the brain implant may need to operate within specific thermal parameters. For example, the brain implant may be designed so that it does not cause a thermal rise of greater than 1 degree Celsius on a surface (e.g., of a housing) of the brain implant.

In some aspects, the brain implant may not include a battery, and instead is wirelessly powered and wirelessly controlled. In some aspects, the brain implant may include a battery that is wireless charged. The brain implant, in some aspects, includes nanotubes (e.g., ˜1 million nanotubes) that connect the brain implant to neurons of a brain tissue. For example, the nanotubes may be coated with a material (e.g., a fluid) that promotes growth and adherence of neurons to the nanotubes. These nanotubes may operate as a heat sink for the brain implant. For example, the adherence of the nanotubes to the neurons may allow heat to be dissipated through the neurons and surrounding tissues, such as through blood flow through capillaries providing blood to the neurons.

However, the time it takes the brain tissue (e.g., neurons, capillaries, etc.) to come into close contact (e.g., adhere) with the nanotubes may be variable. For example, the process may take weeks. Accordingly, during the adherence process, for example, the thermal conductivity of the brain implant to brain tissue is dynamic and unknown, and therefore temperature rise of the implant and surrounding brain tissue would also be a function of the level of contact (e.g., adherence). Without knowing the thermal conductivity, it may not be possible to ascertain the temperature of the implant (e.g., implant surface) based only on the power dissipation at the implant alone. In particular, the amount of temperature rise may be a function of the power dissipated by the receiver 208 and the thermal conductivity of materials surrounding a device (e.g., implant) including the receiver 208.

Therefore, certain aspects described herein provide techniques for controlling the power dissipation of a wireless power receiver (e.g., receiver 208) based on a temperature measured near the wireless power receiver. Accordingly, even if the amount of temperature change in the area surrounding the receiver 208 is unknown based only on the values of the power dissipation in the receiver 208 (e.g., due to a dynamic thermal conductivity of material surrounding the wireless power receiver), the actual temperature change can be used to control the power dissipation.

Further, in some aspects, parameters other than temperature measured near the receiver 208 may be used to control the power dissipation of the receiver 208. For example, certain parameters may be correlated to or indicative of the temperature near the receiver 208, such as, for example, electrical properties of an implant powered by the receiver 208. For example, certain parameters may be correlated to the level of contact or adherence of tissue (e.g., brain tissue, neurons, capillaries, etc.) to nanotubes, and can therefore be used to determine the thermal conductivity of a brain implant including the receiver 208. The determined thermal conductivity can then be used along with the calculated power dissipation at the receiver 208 to determine a temperature rise of the brain implant. Such electrical properties may include an impedance, capacitance, or other electrical property along the nanotubes (or other thermally conductive path between the receiver 208 and material or surrounding thermal environment near the receiver 208 (e.g., brain tissue)). In some aspects, where the parameters measured near the receiver 208 are correlated to properties of a load (e.g., the level of contact of brain tissue to nanotubes of a brain implant), the functionality of a load, or output power of the receiver 208 may be adjusted based on the measured parameters.

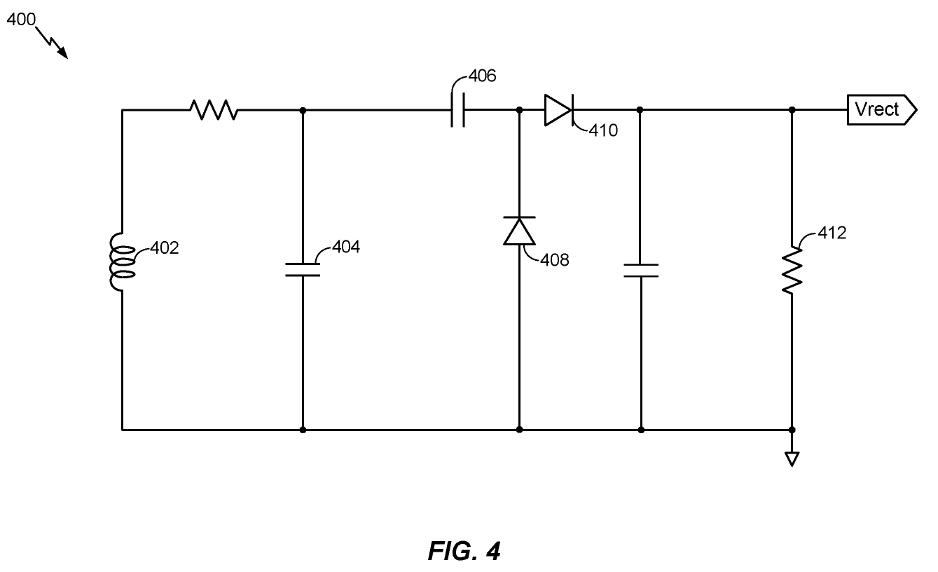

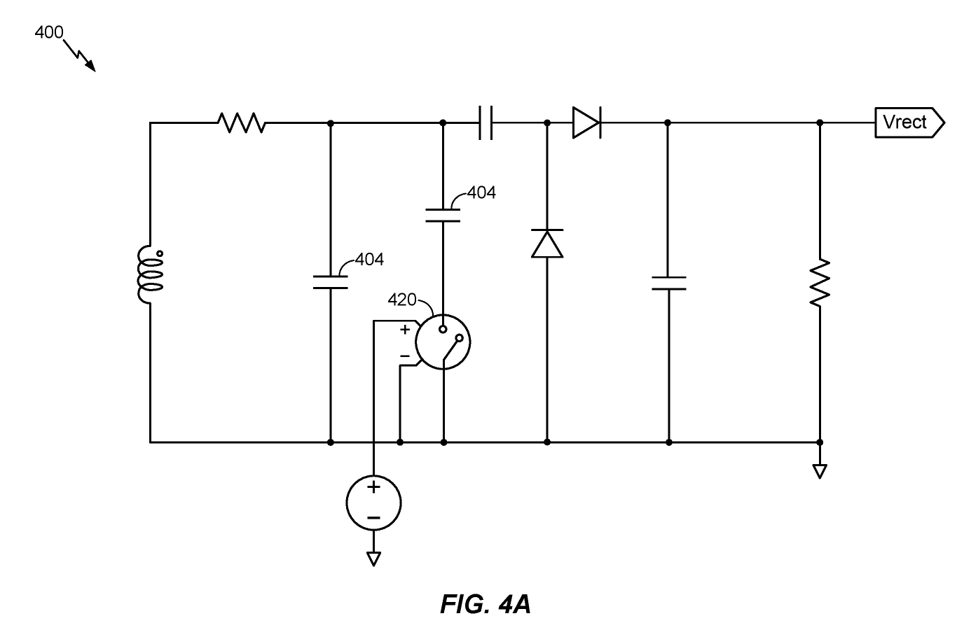

In certain aspects, the power dissipation of a wireless power receiver (e.g., receiver 208) is controlled by adjusting a capacitance of a resonator of the wireless power receiver. For example, FIG. 4 is a circuit diagram of an example of a wireless power receiver 400 (e.g., corresponding to receiver 208), in accordance with some aspects. As shown, FIG. 4 includes an inductor 402, a capacitor 404 coupled in parallel with the inductor 402, and a capacitor 406 coupled in series with the inductor 402. The wireless power receiver 400 further includes diodes 408 and 410. The diodes 408 and 410 may be configured to operate as a rectifier (e.g., passive rectifier) of the wireless power receiver 400. Though not shown, in addition to or alternative to the diodes 408 and 410, the wireless power receiver 400 may include an active rectifier comprising one or more switches (e.g., transistors). For example, each of the diodes 408 and 410 may be replaced by or in parallel with transistors. The wireless power receiver 400 is further coupled to a load modeled by resistor 412, such as the functional components of an implant (e.g., brain implant).

The inductor 402, capacitor 404, and capacitor 406 may be part of a resonant circuit or resonator of the wireless power receiver 400. In certain aspects, the capacitor 404 acts as a shunt tuning capacitor to shunt tune the resonator of the wireless power receiver 400. In certain aspects, the capacitor 406 acts as a series tuning capacitor to series tune the resonator of the wireless power receiver 400. Though each of capacitor 404 and 406 are shown as a single capacitor, in some aspects, the capacitor 404 and/or 406 may be made up of multiple capacitors (e.g., coupled in series and/or parallel) to achieve a particular capacitance. For example, as shown in FIG. 4A, the capacitor 404 is shown as two capacitors coupled in parallel.

In certain aspects, the capacitance (e.g., shunt tuning capacitance and/or series tuning capacitance) of the resonator may be adjusted to adjust a shunt tuning and/or series tuning of the resonator. For example, in certain aspects, the capacitor 404 and/or the capacitor 406 may be variable capacitors that can be controlled to change the capacitance of the capacitor 404 and/or the capacitor 406. In certain aspects, where the capacitor 404 and/or the capacitor 406 is a variable capacitor, there may be additional fixed capacitors in series with, or in parallel with, the capacitor 404 and/or the capacitor 406, depending on the desired capacitance range or voltage rating of the shunt or series capacitance. In some aspects, the capacitance of the variable capacitor 404 and/or variable capacitor 406 is controlled by a controller, such as controller 250.

In certain aspects, the one or more capacitors of the capacitor 404 and/or the capacitor 406 may be selectively coupled or decoupled from the wireless power receiver 400 to adjust a capacitance of the resonator. For example, as shown in FIG. 4A, the wireless power receiver 400 may include a switch 420 (e.g., a transistor, such as a depletion mode field-effect transistor (FET)) coupled in series with one of the capacitors 404. The switch 420 operates to selectively couple or decouple the capacitor 404 from the resonator of the wireless power receiver 400, thereby adjusting a capacitance of the resonator. Similarly, though not shown, the wireless power receiver 400 may include additional capacitors and switches (e.g., in series with the capacitor 406, in parallel with the capacitor 404, etc.) that may be selectively coupled and decoupled to the resonator of the wireless power receiver 400 to modify a capacitance of the resonator of the wireless power receiver 400. In some aspects, the switch 420 and other switches of the wireless power receiver 400 are controlled by a controller, such as controller 250.

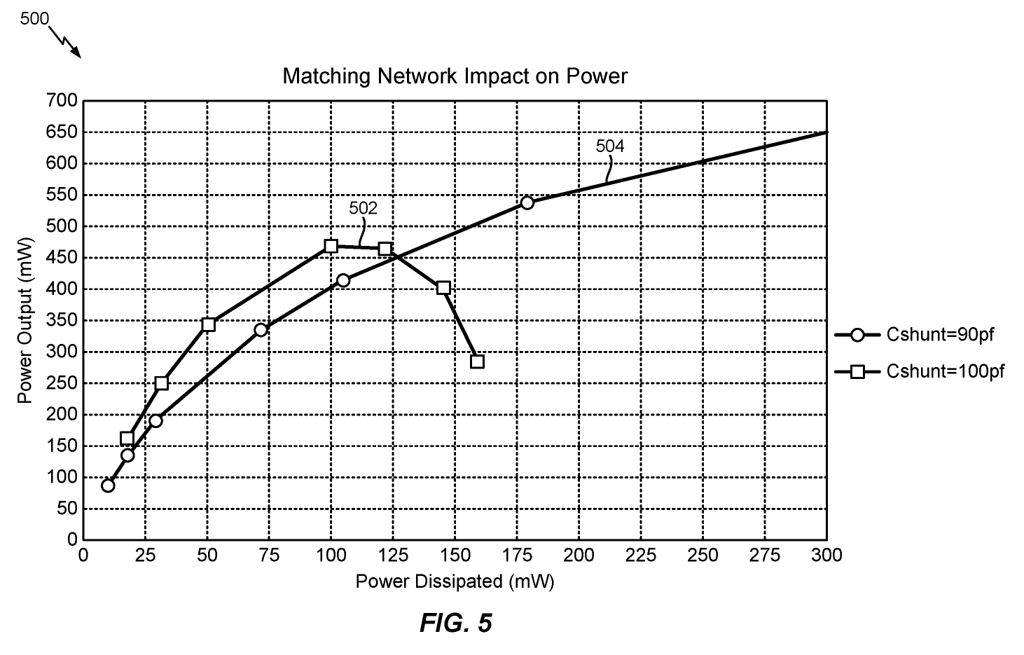

FIG. 5 is a graph 500 that illustrates an example power output of a wireless power receiver (e.g., wireless power receiver 400) versus a power dissipated by the wireless power receiver.

As shown, the x-axis of the graph 500 represents power dissipated in mW by the wireless power receiver, and the y-axis of the graph 500 represents the power output in mW of the wireless power receiver. Line 502 represents the power output versus power dissipated where the resonator of the wireless power receiver includes a shunt tuning capacitor (e.g., capacitor 404) having a capacitance of 100 pF. Line 504 represents the power output versus power dissipated where the resonator of the wireless power receiver includes a shunt tuning capacitor (e.g., capacitor 404) having a capacitance of 90 pF. As can be seen, with the 90 pF capacitance, the wireless power receiver can achieve a higher power output (e.g., above 650 mW), than with the 100 pF capacitance, where the wireless power receiver has a lower maximum power output (e.g., about 475 mW).

However, as can be seen, to operate the wireless power receiver at an output power of 475 mW, the wireless power receiver has lower power dissipation when utilizing the 100 pF capacitance as opposed to the 90 pF capacitance. Accordingly, tradeoffs may be made between power output and power dissipation by adjusting a capacitance of a resonator of the wireless power receiver.

It should be noted that though the change in capacitance of a resonator for changing a power dissipation of the wireless power receiver with respect to a power output of the wireless power receiver is described with respect to a shunt tuning capacitor, similar principles may be applied to changing capacitance of a series tuning capacitor of the resonator to change a power dissipation of the wireless power receiver with respect to a power output of the wireless power receiver.

In certain aspects, the capacitance of a resonator of a wireless power receiver (e.g., wireless power receiver 400) may be adjusted to achieve a desired (e.g., threshold) power output, while remaining below a threshold power dissipation level. In certain aspects, the capacitance of a resonator of a wireless power receiver (e.g., wireless power receiver 400) may be adjusted to achieve a desired (e.g., threshold) power output, while minimizing a power dissipation level.

As discussed herein, the power dissipation level of the wireless power receiver may affect a temperature of the area surrounding the wireless power receiver. Further, in certain aspects, the effect of the power dissipation level on the temperature may be unknown or dynamic due to a changing thermal conductivity of the material surrounding the wireless power receiver. Therefore, for example, in order to ensure a temperature in an area surrounding the wireless power receiver does not exceed a threshold, in certain aspects, the capacitance of the resonator of the wireless power receiver may be adjusted based on a temperature near the wireless power receiver or an electrical characteristic of a thermally conductive path between the wireless power receiver and a surround thermal environment (e.g., neurons of a brain tissue).

For example, in certain aspects, if the measured temperature in an area surrounding the wireless power receiver is above a threshold (e.g., a first threshold that may be close to but below a maximum operating temperature threshold), the wireless power receiver may adjust a capacitance of the resonator of the wireless power receiver to decrease the power dissipation at the wireless power receiver. In certain aspects, if the measured temperature in an area surrounding the wireless power receiver is above a maximum operation temperature threshold, wireless power receiver may decouple the resonator of the wireless power receiver from a rectifier of the wireless power receiver to immediately stop power output and power dissipation.

In certain aspects, in addition to adjusting the capacitance of the resonator of the wireless power receiver, the wireless power receiver communicates with a wireless power transmitter (e.g., transmitter 204) that generates a wireless field (e.g., wireless field 205) to transfer power to the wireless power receiver. For example, in certain aspects, if the temperature at the wireless power receiver is above the threshold, the wireless power receiver may indicate (e.g., via communication channel 219) to the wireless power transmitter to increase an output power of the wireless field generated by the wireless power transmitter. The wireless power receiver may further adjust the capacitance of the resonator for the higher output power from the wireless power transmitter, which may increase the efficiency of wireless power reception by the wireless power receiver and accordingly lower temperature, at the cost of lower efficiency at the wireless power transmitter (e.g., due to a higher power output at the wireless power transmitter). In certain aspects, if the temperature at the wireless power receiver is below the threshold, the wireless power receiver may indicate field transmitted by the wireless power transmitter. The wireless power receiver may further adjust the capacitance of the resonator for the lower output power from the wireless power transmitter. Though the efficiency of the wireless power receiver may accordingly be decreased, efficiency of the overall system including the wireless power receiver and the wireless power transmitter may be increased.

In certain aspects, if the output power of the wireless power receiver is not enough to fully power a load (e.g., a brain implant), and the measured temperature in an area surrounding the wireless power receiver is below the first threshold, the wireless power receiver may adjust a capacitance of the resonator of the wireless power receiver to increase an output power of the wireless power receiver.

In some aspects, the wireless power receiver may not be able to adjust the capacitance of the resonator of the wireless power receiver to both fully power a load and achieve a desired power dissipation or temperature. Accordingly, in some aspects, the wireless power receiver may adjust the capacitance of the resonator to achieve a power output lower than enough to fully power the load, but sufficient to power one or more functions of the load, while still achieving a desired power dissipation or temperature. For example, a brain implant may provide a variety of functions, such as, in-band communications, mixed band radio communications, neuron stimulation, etc. In certain aspects, the brain implant may only run certain functions until the wireless power receiver can output more power while still maintaining the temperature below the first threshold (e.g., until more neurons adhere to the nanotubes).

In certain aspects, the wireless power receiver (e.g., controller 250 of the receiver 208) may be configured to monitor temperature and/or electrical characteristics (e.g., using a sensor 251) near the wireless power receiver versus power output/power dissipation of the wireless power receiver over time and adjust function of a load of the wireless power receiver based on the monitoring. For example, the monitoring may be used to determine characteristics of materials surrounding the wireless power receiver, such as, for a brain implant including the wireless power receiver. For example, the wireless power receiver may be configured to output a specific power output over time (e.g., continuously or at discrete times), such as by running a particular same function of a brain implant, and monitor the temperature and/or electrical characteristics near the wireless power receiver over the same time. The temperature may decrease over time for the same power output by the wireless power receiver, such as, based on changing brain tissue contact level with nanotubes of a brain implant including the wireless power receiver. The controller 250 may determine when the temperature decrease and/or electrical characteristics change over time is relatively unchanging or flat, and then determine that the brain tissue has achieved close contact (e.g., adhered) to the brain implant. Based on this, the controller 250 may determine it is safe to begin operating the brain implant in a full power mode and/or run particular functions of the brain implant.

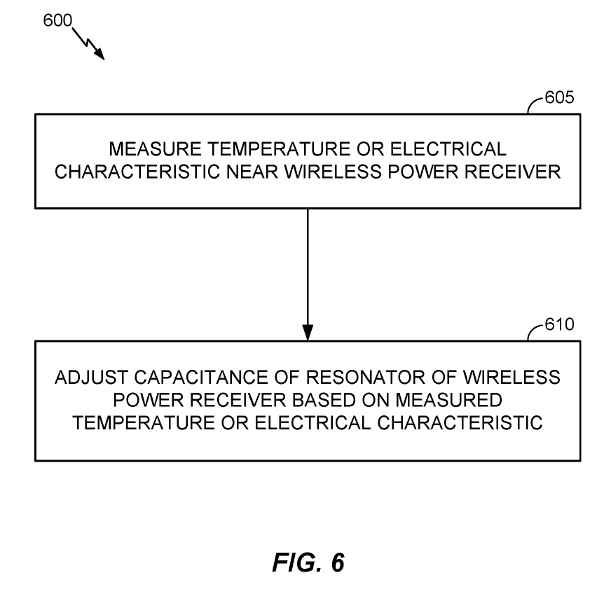

FIG. 6 is a flowchart of example operations for adjusting capacitance in a resonator of a wireless power receiver, in accordance with certain aspects of the present disclosure.

At block 605, at least one of a temperature near a wireless power receiver or an electrical characteristic of a thermally conductive path associated with a load coupled to the wireless power receiver (e.g., a thermally conductive path between the wireless power receiver and a brain tissue or other surrounding thermal environment) is measured. For example, a sensor 251 measures the temperature or electrical characteristic.

At block 610, a capacitance of a resonator of the wireless power receiver is adjusted based on the measured temperature or electrical characteristic. For example, as discussed, if the temperature is above a threshold, the capacitance of the resonator is adjusted to achieve a desired power output at a desired (e.g., lower) power dissipation. In another example, if the change in temperature and/or electrical characteristic over time is substantially flat or unchanging, the capacitance of the resonator is adjusted to achieve a desired power output, such as a sufficient power output to fully power a load.

The method of FIG. 6 may be used to operate/control any of wireless power receivers 208, 400, or 400A, or any other suitable wireless power receiver with a hybrid rectifier.

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The various illustrative logical blocks, modules and circuits described in connection with the present disclosure may be implemented or performed with a general purpose processor, a digital signal processor (DSP), an ASIC, a field programmable gate array (FPGA) or other programmable logic device (PLD), discrete gate or transistor logic, discrete hardware components, or any combination thereof designed to perform the functions described herein. A general-purpose processor may be a microprocessor, but in the alternative, the processor may be any commercially available processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The functions described may be implemented in hardware, software, firmware, or any combination thereof. If implemented in hardware, an example hardware configuration may comprise a processing system in a wireless node. The processing system may be implemented with a bus architecture. The bus may include any number of interconnecting buses and bridges depending on the specific application of the processing system and the overall design constraints. The bus may link together various circuits including a processor, machine-readable media, and a bus interface. The bus interface may be used to connect a network adapter, among other things, to the processing system via the bus. The network adapter may be used to implement the signal processing functions of the physical (PHY) layer. In the case of a user terminal, a user interface (e.g., keypad, display, mouse, joystick, etc.) may also be connected to the bus. The bus may also link various other circuits such as timing sources, peripherals, voltage regulators, power management circuits, and the like, which are well known in the art, and therefore, will not be described any further.

The processing system may be configured as a general-purpose processing system with one or more microprocessors providing the processor functionality and external memory providing at least a portion of the machine-readable media, all linked together with other supporting circuitry through an external bus architecture. Alternatively, the processing system may be implemented with an ASIC with the processor, the bus interface, the user interface in the case of an access terminal), supporting circuitry, and at least a portion of the machine-readable media integrated into a single chip, or with one or more FPGAs, PLDs, controllers, state machines, gated logic, discrete hardware components, or any other suitable circuitry, or any combination of circuits that can perform the various functionality described throughout this disclosure. Those skilled in the art will recognize how best to implement the described functionality for the processing system depending on the particular application and the overall design constraints imposed on the overall system.

It is to be understood that the claims are not limited to the precise configuration and components illustrated above. Various modifications, changes and variations may be made in the arrangement, operation and details of the methods and apparatus described above without departing from the scope of the claims.

What is claimed is:

1. A wireless power receiver comprising:
a resonator comprising an inductor and a capacitor, the resonator being configured to couple to a wireless field, the wireless field inducing a voltage in the resonator, wherein the capacitor is coupled to the inductor, and wherein the capacitor is configured to at least one of shunt tune or series tune the resonator; and
a control circuit configured to at least one of selectively couple the capacitor to the inductor or adjust a capacitance of the capacitor based on at least one of a temperature near the wireless power receiver or an electrical characteristic of a thermally conductive path between the wireless power receiver and a surrounding thermal environment, wherein the control circuit is configured to at least one of selectively couple the capacitor to the inductor or adjust the capacitance of the capacitor to change an efficiency of the wireless power receiver to adjust the temperature near the wireless power receiver.

2. The wireless power receiver of claim 1, wherein the capacitor comprises a variable capacitor and wherein the control circuit is configured to adjust the capacitance of the capacitor.

3. The wireless power receiver of claim 1, further comprising a switch coupled between the inductor and the capacitor, and wherein the control circuit is configured to selectively open and close the switch to selectively couple the capacitor to the inductor.

4. The wireless power receiver of claim 1, wherein the control circuit is configured to at least one of selectively couple the capacitor to the inductor or adjust the capacitance of the capacitor based on the electrical characteristic of the thermally conductive path between the wireless power receiver and the surrounding thermal environment.

5. The wireless power receiver of claim 4, wherein the electrical characteristic comprises at least one of an impedance or a capacitance of the thermally conductive path.

6. The wireless power receiver of claim 4, wherein the thermally conductive path comprises one or more nanotubes, and wherein the electrical characteristic comprises an impedance along the one or more nanotubes.

7. The wireless power receiver of claim 1, wherein the control circuit is configured to at least one of selectively couple the capacitor to the inductor or adjust the capacitance of the capacitor based on the temperature near the wireless power receiver.

8. The wireless power receiver of claim 7, wherein the control circuit is configured to at least one of change a coupling of the capacitor to the inductor or adjust the capacitance of the capacitor when the temperature near the wireless power receiver exceeds a first threshold.

9. The wireless power receiver of claim 8, further comprising a rectifier and a switch coupled to the inductor, the switch being configured to decouple the inductor from the rectifier when the temperature near the wireless power receiver exceeds a second threshold.

10. The wireless power receiver of claim 1, wherein the wireless power receiver is further coupled to a brain implant capable of a plurality of functions having different power requirements, and wherein one or more of the plurality of functions are selectively enabled and disabled based on the at least one of the temperature near the wireless power receiver or the electrical characteristic of the thermally conductive path between the wireless power receiver and the surrounding thermal environment.

11. The wireless power receiver of claim 1, wherein selectively coupling the capacitor to the inductor or adjusting a capacitance of the capacitor changes a power dissipation of the wireless power receiver with respect to a power output of the wireless power receiver.

12. The wireless power receiver of claim 1, further comprising a transmitter configured to transmit a request to a wireless power transmitter generating the wireless field to adjust a power level of the wireless field based on the at least one of the temperature near the wireless power receiver or the electrical characteristic of the thermally conductive path between the wireless power receiver and the surrounding thermal environment, wherein the control circuit is further configured to at least one of selectively couple the capacitor to the inductor or adjust the capacitance of the capacitor based on the adjusted power level.

13. A method for controlling power dissipation in a wireless power receiver, the method comprising:
coupling a resonator to a wireless field to induce a voltage in the resonator;
measuring at least one of a temperature near the wireless power receiver or an electrical characteristic of a thermally conductive path between the wireless power receiver and a surrounding thermal environment; and
adjusting a series tuning or shunt tuning of the resonator based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

14. The method of claim 13, wherein adjusting comprises adjusting a capacitance of a variable capacitor of the resonator.

15. The method of claim 13, wherein adjusting comprises selectively opening and closing a switch to selectively couple a capacitor to an inductor of the resonator.

16. The method of claim 13, wherein the adjusting is performed based on the electrical characteristic of the thermally conductive path between the wireless power receiver and the surrounding thermal environment.

17. The method of claim 16, wherein the electrical characteristic comprises at least one of an impedance and a capacitance of the thermally conductive path.

18. The method of claim 16, wherein the thermally conductive path comprises one or more nanotubes, and wherein the electrical characteristic comprises an impedance along the one or more nanotubes.

19. The method of claim 13, wherein the adjusting is performed based on the temperature near the wireless power receiver.

20. The method of claim 19, further comprising adjusting when the temperature near the wireless power receiver exceeds a first threshold.

21. The method of claim 20, further decoupling the resonator when the temperature near the wireless power receiver exceeds a second threshold.

22. The method of claim 13, wherein the wireless power receiver is further coupled to a brain implant capable of a plurality of functions having different power requirements, and further comprising selectively enabling and disabling one or more of the plurality of functions based on the at least one of the temperature near the wireless power receiver or the electrical characteristic of the thermally conductive path between the wireless power receiver and the surrounding thermal environment.

23. The method of claim 13, further comprising transmitting a request to a wireless power transmitter generating the wireless field to adjust a power level of the wireless field based on the at least one of the temperature near the wireless power receiver or the electrical characteristic of the thermally conductive path between the wireless power receiver and the surrounding thermal environment, wherein adjusting the series tuning or shunt tuning of the resonator is further based on the adjusted power level.

24. The method of claim 13, wherein adjusting the series tuning or shunt tuning of the resonator changes a power dissipation of the wireless power receiver with respect to a power output of the wireless power receiver.

25. A wireless power receiver comprising:
means for measuring at least one of a temperature near the wireless power receiver or an electrical characteristic of a thermally conductive path between the wireless power receiver and a surrounding thermal environment; and
means for adjusting a series tuning or shunt tuning of a resonator of the wireless power receiver based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

26. The wireless power receiver of claim 25, wherein the means for adjusting comprises means for adjusting based on the temperature near the wireless power receiver.

27. The wireless power receiver of claim 25, further comprising means for transmitting a request to a wireless power transmitter generating a wireless field to adjust a power level of the wireless field based on the at least one of the temperature near the wireless power receiver or the electrical characteristic of the thermally conductive path between the wireless power receiver and the surrounding thermal environment, wherein adjusting the series tuning or shunt tuning of the resonator is further based on the adjusted power level.

28. A computer-readable storage medium having instructions stored thereon for performing a method for controlling power dissipation in a wireless power receiver, the method comprising:
measuring at least one of a temperature near the wireless power receiver or an electrical characteristic of a thermally conductive path between the wireless power receiver and a surrounding thermal environment; and
adjusting a series tuning or shunt tuning of a resonator of the wireless power receiver based on the at least one of the temperature near the wireless power receiver or the electrical characteristic of the thermally conductive path between the wireless power receiver and the surrounding thermal environment to change an efficiency of the wireless power receiver to adjust the temperature near the wireless power receiver.

29. The computer-readable storage medium of claim 28, wherein adjusting comprises adjusting based on the temperature near the wireless power receiver.

30. The computer-readable storage medium of claim 28, wherein the method further comprises transmitting a request to a wireless power transmitter generating a wireless field to adjust a power level of the wireless field based on the at least one of the temperature near the wireless power receiver or the electrical characteristic of the thermally conductive path between the wireless power receiver and the surrounding thermal environment, wherein adjusting the series tuning or shunt tuning of the resonator is further based on the adjusted power level.
